(19) United States
(12) Patent Application Publication
(10) Pub. No.: US 2018/0248147 A1
(43) Pub. Date: Aug. 30, 2018

(54) FABRICATION OF COLOR CONVERSION LAYER BY ADHESIVE TRANSFER METHOD

(71) Applicant: SABIC Global Technologies B.V., Bergen op Zoom (NL)

(72) Inventors: Sang Hoon KIM, Seoul (KR); Ho Kyoon CHUNG, Gyeonggi-do (KR); Jo DEOK SU, Gyeonggi-do (KR); Subin JUNG, Gyeonggi-do (KR)

(73) Assignee: SABIC Global Technologies B.V.

(21) Appl. No.: 15/758,008

(22) PCT Filed: Sep. 10, 2016
(86) PCT No.: PCT/IB2016/055409

§ 371 Date: Mar. 7, 2018

Related U.S. Application Data
(60) Provisional application No. 62/217,445, filed on Sep. 11, 2015.

(51) Int. Cl. H01L 51/50; H01L 51/56; H01L 51/00; C09K 11/02; C09K 11/77; B32B 37/00; B32B 37/12; B32B 37/18; B32B 7/12; B32B 27/08; B32B 27/20

(52) U.S. Cl. CPC H01L 51/5036; B32B 2457/206; H01L 51/003; C09K 11/02; C09K 11/7706; B32B 37/025; B32B 37/12; B32B 37/182; B32B 7/12; B32B 27/08; B32B 27/20; H01L 2251/5369; H01L 2251/558; H01L 2251/303; B32B 2264/102; B32B 2307/4026; B32B 2307/422; H01L 51/56

(57) ABSTRACT

A composite layered structure and light-emitting device using the composite layered structure is disclosed. The camposite layered structure includes a substrate and one or more layers of phosphor film disposed on the substrate. The phosphor film includes a resin material and a phosphor material wherein the phosphor material comprises phosphor microparticles sized from 1 μm to 10 μm and phosphor nanoparticles sized from 10 nm to 900 nm.

### RELATED APPLICATION

This application claims priority to and the benefit of U.S. Patent Application No. 62/217,445, filed Sep. 11, 2015, which is incorporated herein by reference in its entirety.

### TECHNICAL FIELD

The disclosure relates to phosphor film and more particularly, to phosphor film used as a color conversion layer (CCL) in a light-emitting device and methods of forming the same.

### BACKGROUND

Today, light emitting diodes (LEDs) are increasing used in lighting applications because they are inexpensive and more energy efficient than other conventional lighting sources. In recent years, industry has been largely focused on the development of white LEDs due to the high demand for the efficient production of white light. To date, there are three different types of organic light emitting devices (OLEDs) that have been developed to produce white light. One type of white OLED has a single white emissive layer structure that produces white light. The single white emissive layer in this structure consists of a single active organic layer that is doped with different kinds of emissive materials, such as fluorescent and phosphorescent materials. Blends of polymers may be used to extend the emission spectrum to achieve white light. While the fabrication method of the single white emissive layer structure is simple and inexpensive, it is very difficult to optimize the various fabrication parameters to achieve good color rendering without significantly reducing the OLED's efficiency.

The second and most widely used white OLED is a multilayered structure composed of separate red, blue and green emitting layers. This multilayered structure produces white light through the simultaneous emission of light from each of the red, blue and green emitting layers. However, this multilayered structure tends to suffer from color stability problems due to the degradation of the emitters in each of the colored layers at different rates. This degradation of the different emitters ultimately leads to changes in the integrity of the white light over time. Furthermore, there are inherent challenges associated with the optimization of the multiple layers to obtain white light of a desired quality.

The third type of white OLED is a hybrid OLED and is formed using a CCL with a blue emitting layer to produce white light. The hybrid OLED is shown in FIG. 1. Red and green emitting layers are not used in the hybrid OLED and only a blue emitting layer is applied to the substrate. The CCL contains a phosphor material that scatters a portion of the light from the blue emitting layer. The combination of the light emitted from the phosphor material and the unabsorbed light from the blue emitting layer produces white light. Because this hybrid OLED uses only one emission layer, the fabrication process is simple and it has improved color stability.

The hybrid OLED device, however, also has some drawbacks. One major drawback is that the phosphor material in the CCL on the OLED produces a colored appearance that is often yellow or yellowish when the device is in the off-state. When the device is turned on, the device produces bright white light. However, when the device is turned off (i.e., the LED is not emitting a light), the device appears yellow under ambient light. The yellow color is due to the presence of a yellow-emitting phosphor material that is used in the CCL.

This phenomenon is due to the intrinsic nature of the phosphor material, which absorbs the white ambient light and converts the light to yellow when the OLED is off or the blue emitting layer is not emitting any blue light through the CCL. This phenomenon is undesirable from an aesthetic point of view because white is more desirable and is generally considered more attractive than yellow colors. Additionally, the yellow or the non-white appearance of the hybrid OLED device in the off-state tends to cause confusion among users, who may mistakenly think that the hybrid OLED does not emit white light when it is turned on.

Another drawback to the hybrid OLED is the difficulty associated with the application of phosphor layers to a substrate. The density and the thickness of the phosphor film is critical to ensuring the color quality of the light produced. There are many conventional coating methods such as solution coating, extrusion, and casting that are currently used to form a phosphor layer onto the OLED substrate. However, it is difficult to achieve consistent and higher packing density films using these methods. Irregularities and damage to the phosphor layer film is also common using these methods.

Therefore, there is a need for improved light-emitting devices and a process for forming such devices that provide a white color when the device is in an off-state while still maintaining the luminesce efficiency of the device and the brightness of the white light. There is also a need for improved methods of applying phosphor material to substrates that create high packing density phosphor films. Accordingly, the disclosed light-emitting devices and processes are directed at overcoming one or more of these disadvantages in currently available OLEDs.

### SUMMARY

In accordance with on aspect of the disclosure, a composite layered structure is disclosed. The composite layered structure includes a substrate and one or more layers of phosphor film disposed on the substrate. The phosphor film includes a resin material and a phosphor material wherein the phosphor material comprises phosphor microparticles sized from 1 micrometer (μm) to 10 μm and phosphor nanoparticles sized from 10 nanometer (nm) to 900 nm.

In accordance with one aspect of the disclosure, a light-emitting device is disclosed. The light-emitting device includes a light source operably connected to a composite layered structure. The composite layered structure includes a substrate and one or more layers of phosphor film disposed on the substrate. The phosphor film includes a resin material, phosphor microparticles sized from 1 μm to 10 μm and phosphor nanoparticles sized from 10 nm to 900 nm and the phosphor film has a surface packing density that ranges from 92% to 97%.

### BRIEF DESCRIPTION OF THE DRAWINGS

The above-mentioned and other features and advantages of this disclosure, and the manner of attaining them, will become apparent and be better understood by reference to the following description of one aspect of the disclosure in conjunction with the accompanying drawings, wherein:

FIG. 1 is a side view schematic illustration of a hybrid OLED according to one aspect of the present disclosure.

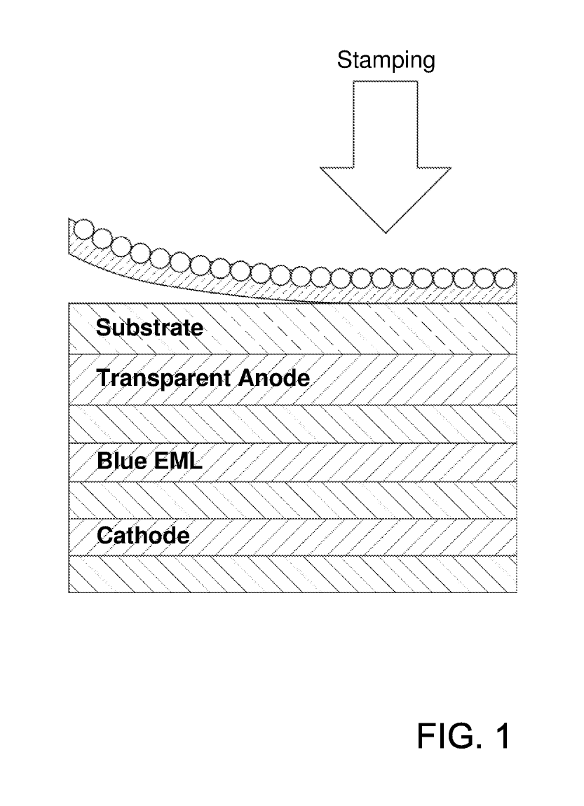

FIG. 2 is a schematic illustration of fabricating a CCL according to one aspect of the present disclosure.

FIG. 3 shows schematic diagrams of field emission scanning electron microscope (FE-SEM) photographs top views of phosphor film layers formed using different phosphor coating methods.

FIG. 4A shows graphs external quantum efficiency (EQE) of hybrid OLEDs fabricated using different phosphor coating methods.

FIG. 4B shows the CIE coordinate of hybrid OLEDs fabricated using different phosphor coating methods.

FIG. 4C shows the EL spectra of hybrid OLEDs fabricated using different phosphor coating methods.

FIG. 5 shows FE-SEM photographs of enlarged cross-sectional and top views of a phosphor film layer composed of conventional phosphor particles formed using an adhesive transfer method.

FIG. 6 shows a FE-SEM photograph of an enlarged top view of conventional phosphor particles, phosphor microparticles, and phosphor nanoparticles according to one aspect of the present disclosure

FIG. 7 shows a FE-SEM photograph an enlarged cross-sectional view and an enlarged top view of a mixture of phosphor microparticles and nanoparticles according to one aspect of the present disclosure.

FIG. 8 shows the electroluminescence (EL) spectrum of hybrid OLEDs with a variation in the number of phosphor film layers according to one aspect of the present disclosure.

FIG. 9 shows the CIE 1931 x,y chromaticity diagram for hybrid OLEDs with a variation in the number of phosphor film layers according to one aspect of the present disclosure.

### DETAILED DESCRIPTION

The composite layered structures disclosed herein comprise a substrate and one or more layers of phosphor film disposed on the substrate. The phosphor film comprises a resin material and a phosphor material that includes phosphor microparticles sized from 1 μm to 10 μm and phosphor nanoparticles sized from 10 nm to 900 nm. The layers of phosphor film and the application of the phosphor film to form the composite layered structure are described in further detail below.

In one aspect of the disclosure, the phosphor film may be disposed on a substrate surface to form a composite layered structure. The substrate is generally configured to support the various layers of the composite layered structure, including the phosphor film. The thickness of the substrate is not particularly limited. In one aspect, the thickness of the substrate is 40 μm or more. In another aspect, the thickness of the substrate is 60 μm or more. In yet another aspect, the thickness of the substrate is preferably 5000 μm or less, and more preferably 3000 μm or less.

In some aspects, the substrate may be a flexible substrate. In other aspects, the substrate may have at least one reflective surface. In one aspect, the phosphor film may be disposed on the reflective surface of the substrate.

In some aspects, the substrate may be a metal, film, glass, ceramic, paper or combinations thereof. Specific examples of the substrate may include, but are not limited to a plate or a foil of metal such as aluminum (including aluminum alloy), zinc, copper and iron; a film made of plastic such as cellulose acetate, polyethylene terephthalate (PET), polyethylene, polyester, polyamide, polyimide, polystyrene, polypropylene, polycarbonate, polyvinyl acetal, aramid and polyphenylene sulfide; and paper having plastic (polyethylene, polypropylene, polystyrene, or the like) laminated thereon or paper coated with plastic (polyethylene, polypropylene, polystyrene, or the like), paper or a plastic film having the above-mentioned metal laminated thereon or vapor-deposited thereon.

The phosphor film includes a resin material and a phosphor material. The phosphor film comprises a phosphor material that advantageously includes a combination of phosphor microparticles and phosphor nanoparticles. The phosphor microparticles may be sized from 1 μm to 10 μm. The phosphor nanoparticles may be sized from 10 nm to 900 nm.

In one aspect of the disclosure, the phosphor material is configured to convert light emitted by a light source such as a LED into light having a different wavelength. For example, the phosphor material may be configured to convert the light emitted by an LED to a higher or lower wavelength as needed. In one aspect, the phosphor material may be used to form a CCL in a light-emitting device. For example, if an LED emits blue light in the blue spectral range of 450-490 nm, then the CCL may contain a layer of phosphor material for converting some of this radiation to a different spectral range. Preferably, the phosphor material is configured to convert most or all of the radiation from the LED to the desired spectral range. Phosphor materials suitable for this purpose are generally known in the art and may include, but are not limited to inorganic materials such as yttrium aluminum garnet (YAG) phosphors.

The phosphor material may include red-emitting phosphors, green-emitting phosphors, and yellow-emitting phosphors. In one aspect, the phosphor material may comprise a mixture of red-emitting phosphor, green-emitting phosphor and yellow-emitting phosphor.

The phosphor material is typically in the form of a solid powder. The phosphor powder may be composed of a mixture of phosphor particles, phosphor microparticles, phosphor nanoparticles or combinations thereof. The phosphor particles or phosphor microparticles may have an average diameter that ranges in size from 1 micron to 100 microns. In one aspect of the present disclosure, the average diameter of the phosphor particles is less than 50 microns. In another aspect of the present disclosure, the average diameter of the phosphor particles is less than 20 microns. In yet another aspect of the present disclosure, the average diameter of the phosphor particles is less than 10 microns. In yet another aspect of the present disclosure, the average diameter of the phosphor nanoparticles used in the phosphor powder ranges from 10 nm to 900 nm. The size of the phosphor particles is generally selected based on the desired thickness of the phosphor film and the overall thickness of the composite layered structure or the light-emitting device. The term “phosphor particle” as used herein encompasses particles of any size or dimension that are composed of phosphor material, including nanoparticles and microparticles as well as larger sized particles.

In some aspects of the disclosure, the surface packing density of the phosphor material in the phosphor film may range from 90% to 97%. As explained in further detail below, higher surface packing densities of phosphor film offer certain advantageous such as thinner film layers and improved color quality. The packing density of the phosphor material in the phosphor film is typically due to a number of variables including the density of the phosphor material in the film layer, the average particle size, particle size distribution and particle shape.

In some aspects of the disclosure, the phosphor material is present in the phosphor film from 90% to 99% by weight based on the total weight of the phosphor film. In some aspects, the phosphor film has a thickness that ranges from 20 μm to 40 μm.

The phosphor film further includes a resin material. The resin material used in the present disclosure is a resin material that is suitable for containing a phosphor material therein, and for forming a film. Accordingly, any resin material may be employed as the resin material as long as it allows the phosphor material to be uniformly dispersed therein and can form a film. A uniform distribution of the phosphor powder in the resin material and throughout the phosphor film is generally preferred to achieve a consistent color quality of light from a light-emitting device. In some aspects, the resin material is present in the phosphor film from 1% to 10% by weight based on the total weight of the phosphor film.

Specific examples of the resin material include a silicone resin, an epoxy resin, a polyallylate resin, a PET modified polyallylate resin, a polycarbonate resin (PC), cyclic olefin, a polyethylene terephthalate resin (PET), a polymethylmethacrylate resin (PMMA), a polypropylene resin (PP), modified acryl resin, a polystyrene resin (PE), and an acrylonitrile-styrene copolymer resin (AS). The resin material may include combinations or mixtures of these and/or other suitable materials. For example, additives may be added to the resin material to improve or alter certain properties of the phosphor film as needed.

In some aspects of the present disclosure, the resin material may be transparent or translucent. In one aspect, silicone resin or epoxy resin may be preferred as a resin material because they are transparent. Furthermore, the silicone resin may be particularly preferable as a resin material because of its heat resistant properties.

In another aspect of the present disclosure, the resin material may be curable. For example, the resin material may be an ultraviolet (UV)-curable or thermally curable resin. The resin material may also in sonic aspects include a curing agent for this purpose. Other suitable film forming methods known in the art may be used to form the phosphor film and the disclosure is not limited in this regard. These methods may include but are not limited to, molding, casting and extrusion techniques. The phosphor film may be spray deposited, spun, deposited by electrophoresis or formed by any other technique. In one aspect of the disclosure, these methods may be used in combination with the adhesive transfer method disclosed herein.

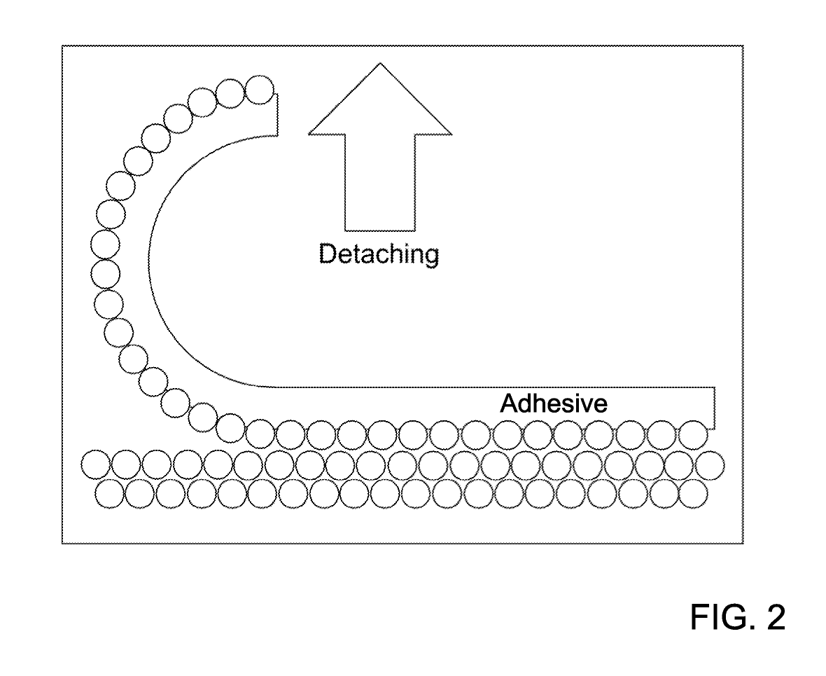

In some aspects, the one or more layers of phosphor film are used as a CCL. CCLs are known to be useful for generating white light by having an LED emitting light of a first color and mixing this light with light of a second color generated by partially converting the light having the first color. For example, FIG. 2 schematically illustrates the fabrication of a CCL by an adhesive transfer method. As explained in further detail below, the adhesive transfer method makes it possible to apply more than one layer of phosphor film to a substrate.

In one aspect of the disclosure, the CCL may have only one layer of phosphor film. In another aspect, the CCL may have more than one layer of phosphor film. For example, a CCL may have two layers of phosphor film or three layers of phosphor film. The number of layers of phosphor film is not limited in this regard.

In one aspect, the CCL may be composed of multiple layers of phosphor film that are different from each other. In other words, each layer of phosphor film may have a different composition or may be composed of a different phosphor material. For example, FIG. 2 shows a CCL that is composed of a first layer, a second layer and a third layer. The first layer is composed of a red-emitting phosphor material. The second layer is composed of a green-emitting phosphor material. The third layer is composed of a yellow-emitting phosphor material. In yet another aspect, the CCL may be composed of multiple layers of phosphor film that have the same composition and/or the same thickness.

The layers of phosphor film may be applied to the substrate using an adhesive transfer method. In the adhesive transfer method, phosphor film is initially provided on a support layer used for the transfer of the phosphor film layer. The phosphor film may be provided on the support layer using any means known in the art. For example, the phosphor film may be applied to the support layer by coating, spraying, extruding, etc. In some aspects, an adhesive may also be used to attach the phosphor film to the support layer. It is generally preferred, however, that the phosphor film is weakly attached to the support layer. A weak attachment of the phosphor film to the support layer will promote the release of the support layer later in the transfer process, whereas a strong attachment or bond between the phosphor film layer and the support layer may make it more difficult to remove the phosphor film from the support layer.

The support layer is not limited and is configured to be detached from the phosphor film such that the support layer is not part of the composite layered structure. The support layer may include a release layer on the surface of the support layer that is also in direct contact with the phosphor film. The release layer may be present to assist with and facilitate the separation of the phosphor film from the support layer during the transfer process. Suitable materials for the release layer may include but are not limited to silicones, polycarbonates, and polyacrylates.

In one aspect of the disclosure, an adhesive material may be deposited on the surface of the phosphor film opposite the support layer. The adhesive material is provided solely to facilitate the transfer of the phosphor film to the substrate or to other phosphor film layers such that the composite layered structure is formed. The adhesive material may be deposited on the entire surface area of the phosphor film such that an adhesive layer or coating is formed. Alternatively, the adhesive material may be deposited on only a portion of the phosphor film surface. The adhesive material is generally deposited as needed to adhere the phosphor film to the substrate. It is generally preferred that the adhesive material is not deposited on the periphery edges of the phosphor film and the support layer because it may make it more difficult to detach the phosphor film from the support layer. In some aspects, the adhesive material may be a wax, resin, or glue. In other aspects, the adhesive material may include a metal or an alloy.

In some aspects of the disclosure, the adhesive material may be deposited on the surface of the substrate in addition to the surface of the phosphor film. In yet other aspects of the disclosure, the adhesive material may be deposited on the surface of the substrate instead of the surface of the phosphor film.

The phosphor film may then be transferred to the substrate to form the composite layered structure after the adhesive material is applied. For example, the surface of the phosphor film to be transferred may be contacted with the surface of the substrate. At least one of these surfaces of the substrate and the phosphor film or both will have some adhesive material to assist with bonding the surfaces together. In some aspects, placing the two surfaces in direct contact with each other may adhere the phosphor film to the substrate. In other aspects, pressure may be applied or a heat treatment may be needed. Other techniques for bonding may also be used.

Once bonded, the phosphor film layer may be separated from the support layer to complete the transfer of the phosphor film layer to the substrate or the composite layered structure. The separation of the support layer from the phosphor film layer may be achieved mechanically by use of tools such as a knife blade or for example by using a chemical treatment or heat treatment as needed. Other techniques may also be used.

The adhesive transfer method disclosed herein and variations of this method may be repeated to apply multiple layers of phosphor film sequentially. For example, a first layer of phosphor film may be applied to the substrate, a second layer of phosphor film may be then be applied to the first layer of phosphor film and a third layer of phosphor film may be applied to the second layer of phosphor film. Each layer of phosphor film may be applied using the adhesive transfer method.

The composite layered structure may further include one or more whitening layers disposed over the one or more layers of phosphor film. The whitening layers may be directly deposited onto the phosphor layers or the whitening layers may be spaced apart from the CCL. For example, the whitening layers may be separated from the phosphor film layer by other materials or components that are present in a light-emitting device.

The whitening layers are generally configured to whiten the appearance of a light-emitting device in its off-state. The whitening layers reduce the absorption of ambient light by the phosphor layer to produce a white appearance for the device in the off-state. In one aspect, only one whitening layer may be necessary to provide a white appearance in the off-state. In another aspect, multiple layers may be needed to achieve a white appearance for the device in the off-state.

The whitening layer comprises a plurality of whitening particles. In one aspect of the present disclosure, the whitening particles may include TiO₂, Al₂O₃, ZrO, ZnO ZrO₂ or mixtures thereof. Other materials may be used for the whitening particles if they are white or have a whitening effect on the light-emitting device under ambient light. The appearance of the light-emitting device having a CCL using phosphor film should appear much whiter when the light-emitting device is turned off. Additionally, the whitening particles and other materials used to form the whitening layer are preferably selected such that they do not adversely affect the efficiency or the brightness of the light-emitting device.

The whitening particles may be present in the whitening layer in an amount from 5% to up to 50% by weight based on the total weight of the of the whitening layer. Generally, as the amount of the whitening particles increases, a whiter appearance results when the light-emitting device is in the off-state.

In some aspects, the whitening particles may be a mixture of microparticles and nanoparticles. The whitening particles may have an average diameter that ranges in size from 1 micron to 100 microns. In one aspect of the present disclosure, the average diameter of the whitening particles is less than 50 microns. In another aspect of the present disclosure, the average diameter of the whitening particles is less than 20 microns. In yet another aspect of the present disclosure, the average diameter of the whitening particles is less than 10 microns. In yet another aspect of the present disclosure, the average diameter of the whitening nanoparticles used in the whitening layers ranges from 10 nm to 900 nm. In some aspects, the size of the whitening particles and the density of the whitening particles in the whitening layers may at least in part determine the thickness and/or the whitening performance of the whitening layer.

The whitening particles may be mixed with a resin material and/or an encapsulant. The resin material used in the phosphor film layers may be the same resin material used in the whitening layers. An encapsulant material may provide a moisture and/or oxygen barrier to the light-emitting device to protect the device from degradation. The encapsulant may be composed of organic or inorganic materials. For example, the encapsulant may be made of silicone, epoxy, glass, plastic or other materials. The encapsulant is preferably transparent or translucent. The whitening particles may be uniformly distributed throughout the binder material and/or encapsulant to ensure a uniform white color.

Light-emitting devices, especially OLEDs that produce white light are disclosed herein. In one aspect of the present disclosure, hybrid OLEDs or OLEDs that use a blue emitting layer and a CCL containing one or more phosphor film layers are disclosed herein. Although the discussion of the preferred embodiments relates to OLEDs, it will be understood by those skilled in the art that the disclosure is in fact applicable to any device, especially those emitting light, and especially those emitting white light.

The light-emitting device may include a composite layered structure comprising a substrate and one or more layers of phosphor film disposed on the substrate. The light-emitting device further includes an LED disposed on the substrate opposite the phosphor film layers. The light-emitting device may further include at least one whitening layer. The whitening layer is disposed over the LED and the one or more layers of phosphor film.

In one aspect of the present disclosure, the one or more whitening layers are configured to provide the light-emitting device with a white appearance when the device is in its off-state. The light-emitting device may have an on-state wherein the device emits light and an off-state wherein the device does not emit any light. When the light-emitting device is in its on-state, the LED is illuminated. Conversely, when the light-emitting device is in its off-state, the LED is not illuminated. In one aspect of the present disclosure, the light-emitting device emits white light in its on-state. In another aspect, the light-emitting device does not emit any light in its off-state but has white appearance in its off-state. The light-emitting device may be powered by a variety of methods known in the art. For example, the LED may be connected to a circuit or an element that provides current to the LED thereby illuminating the LED when the device is turned on.

In one aspect, the LED is a blue LED or blue light emitting diode, also referred to as a blue light emitter and is configured to emit blue light. For example, the LED emits light in the blue portion of the visible spectrum approximately 400-480 nm. As set forth above, the emission of blue light may be used to produce white light. The present disclosure may, however, be implemented using various illumination sources such as fluorescent lights or LEDs that use arrays of red, green or blue LEDs. In one aspect of the disclosure, the light emitting device may use an array of red, green, and blue LEDs that collectively produce white light. For example, aspects of the present disclosure contemplate use of any color emitter.

In some aspects, the light-emitting device may include one LED or more than one LED. Any semiconductor material known in the art may be used to form the LED. For example, gallium nitride may be used to form a blue LED for use with the present disclosure. The color of the light emitted from the LED is generally a function of the semiconductor materials used to form the LED. The LED may emit light in various configurations and the disclosure is not limited in this regard. For example, the LED may be a bottom-emitting LED, a top-emitting LED, a side-emitting LED or a combination thereof.

### EXAMPLES

### Example 1

### Hybrid OLEDs Formed Using Different Phosphor Coating Techniques

The performance of hybrid OLEDs composed of phosphor film applied using different coating techniques was compared. Each of the hybrid OLEDs tested used a YAG phosphor material and a poly(dimethylsiloxane) (PDMS) resin material to form a phosphor film layer. The phosphor film layers, however, were coated using the following coating techniques: (1) adhesive transfer, (2) casting, (3) slot die and (4) particle dispersion.

The thickness of the phosphor film layer was determined for each device formed. The coating techniques resulted in phosphor film layers having thicknesses ranging from 16 um to 500 um. Adhesive transfer produced a phosphor film layer having a thickness of 36 um. Casting produced a phosphor film layer having a thickness of 160 um. The slot die technique produced a phosphor film layer having a thickness of 500 um. The particle dispersion technique produced a phosphor film layer having a thickness of 16 um.

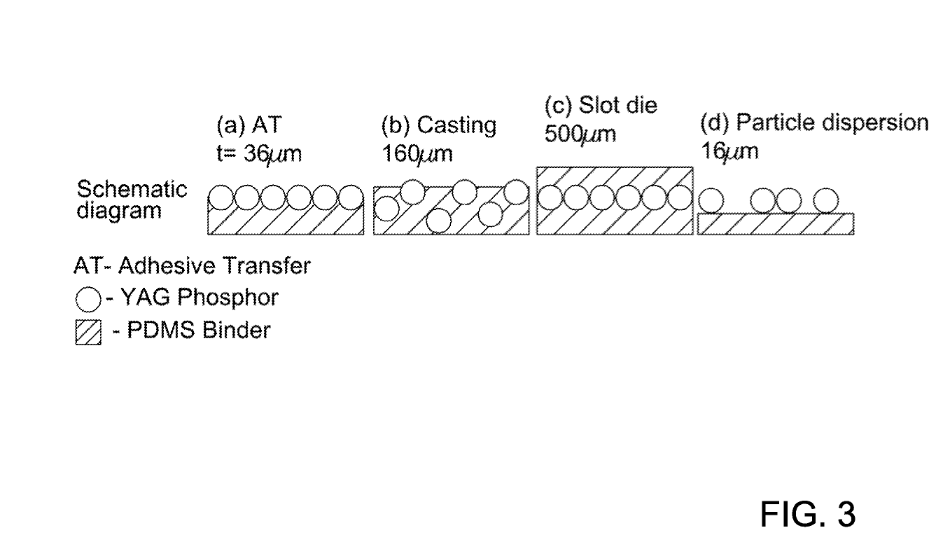

FE-SEM images of the top and cross-sectional views of the phosphor film layers produced using the different coating techniques were obtained. FIG. 3 presents schematic diagrams of these images for phosphor film layers produced by (a) adhesive transfer, (b) casting, (c) slot die, and (d) particle dispersion techniques as well as their respective thicknesses, t. As represented in the diagrams of FIG. 3, the phosphor film produced by adhesion transfer exhibited the highest surface packing density compared to phosphor films produced by other coating methods. For example, the surface packing density of the phosphor film formed by adhesive transfer method was 92%. Surface fill factor values were derived according to the top view FE-SEM images. The surface fill factor for the adhesive transfer phosphor film layer was approximately 90. The surface fill factor for the phosphor film layer formed by casting was approximately 40. The surface fill factor for the phosphor film layer formed by slot die was 0. The surface fill factor for the particle dispersion phosphor film layer was approximately 20.

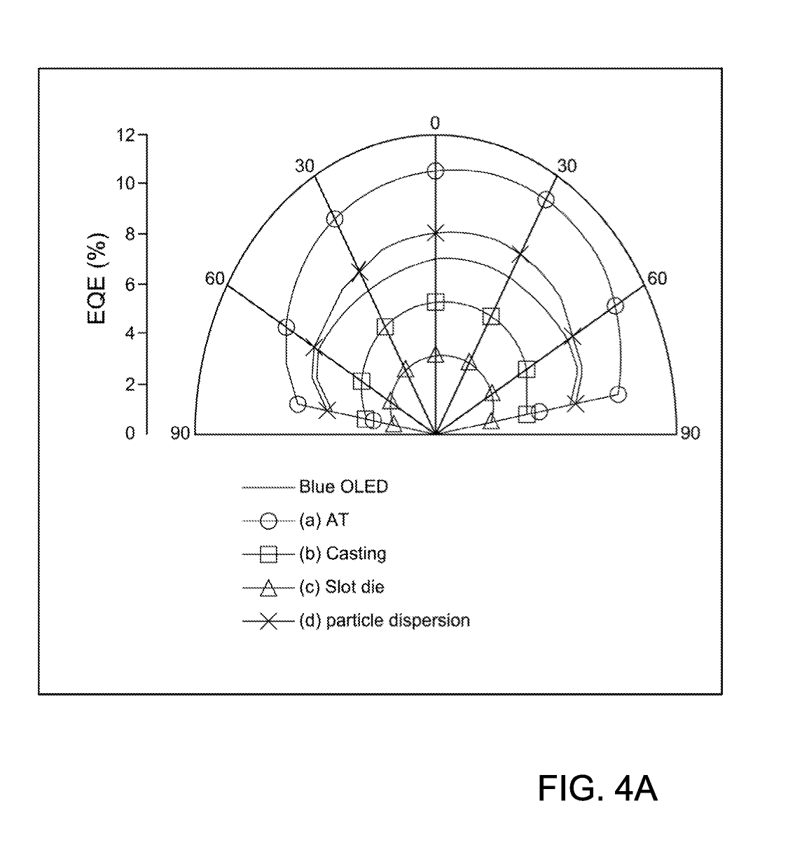

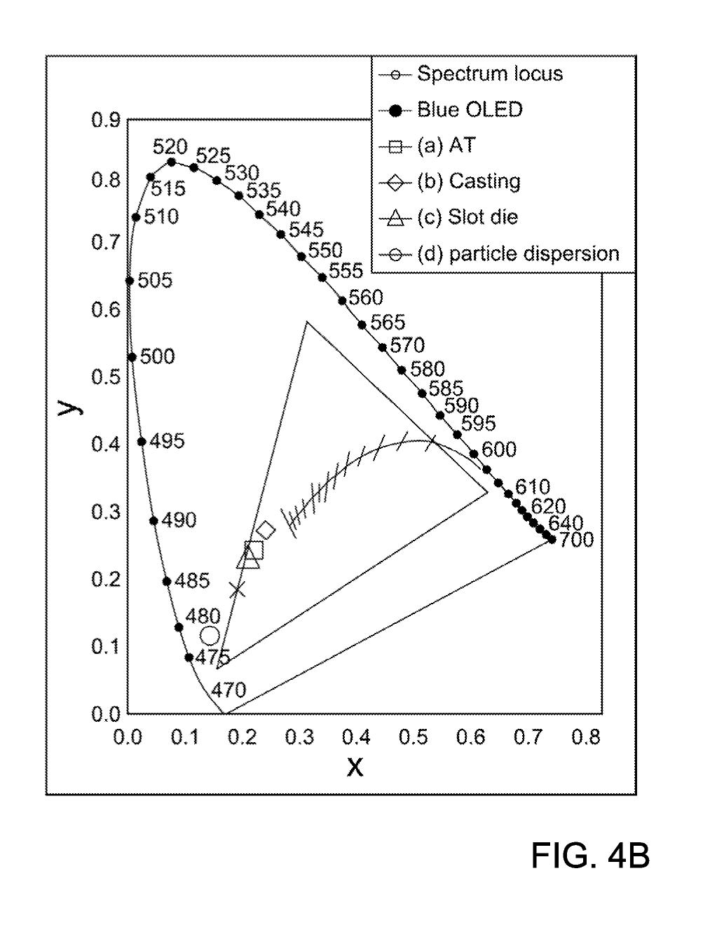

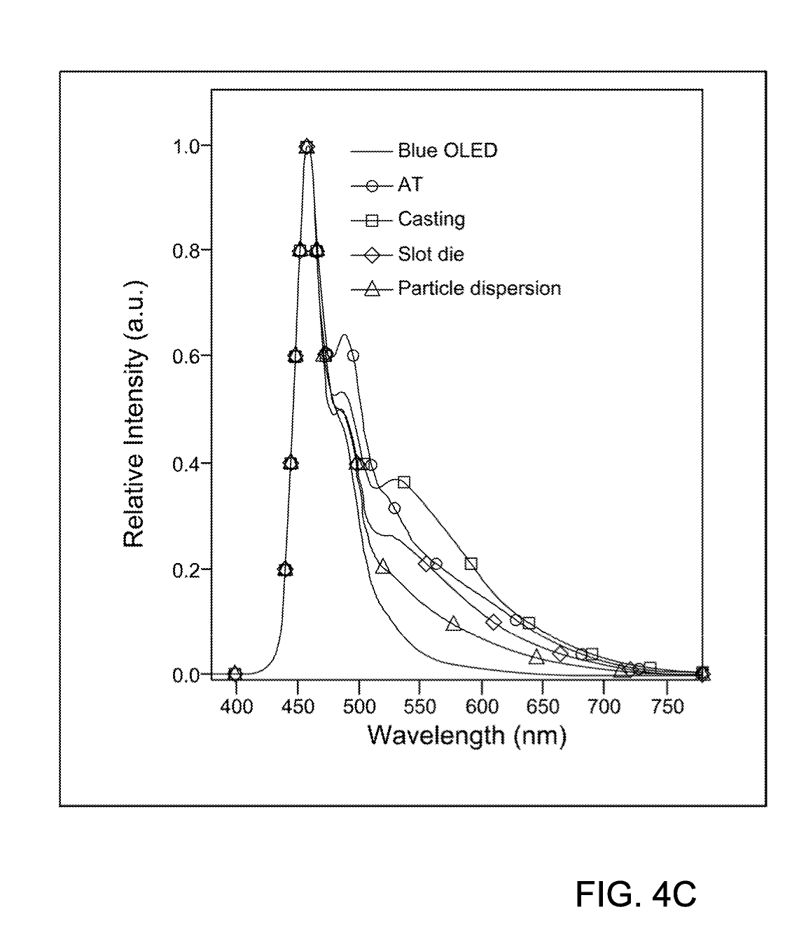

The devices formed were tested for color and efficiency and the results are reported in FIGS. 4A-4C. FIGS. 4A to 4C shows comparison between the EQE as in FIG. 4A, CIE coordinates as in FIG. 4B, and EL spectra as in FIG. 4C of the hybrid OLEDs formed using the different phosphor coating methods. As shown in FIG. 4A, the external quantum efficiency was the highest for the hybrid OLED formed using the adhesive transfer method. There was no significant variation in CIE values for the different phosphor coating methods. FIG. 4B. It is believed that the slight variations in CIE values between the different devices were because of differing amounts of phosphor present in the films formed.

The EL spectral data obtained shows higher relative intensity values for the hybrid OLED with the adhesive transfer phosphor film layer. This spectral data further demonstrates that the adhesive transfer method provides a phosphor film with the highest surface packing density thereby achieving greater efficiency and light quality.

The color conversion and out-coupling efficiencies were also calculated for each device. These results are presented below in Table 1.

TABLE 1
Scattering Effect

| | AT | Casting | Slot die | Particle dispersion |
|---|---|---|---|---|
| Conversion efficiency | 22% | 26% | 21% | 14% |
| Out-coupling | 142% | 71% | 43% | 109% |

The out-coupling efficiency calculated for the hybrid OLED device that used the adhesive transfer method was significantly higher than the comparative devices. For example, the comparative devices that used other phosphor coating methods had out-coupling efficiencies ranging from 43% to 109%, whereas the hybrid OLED device using the adhesive transfer method had an out-coupling efficiency of 142%. Again, this result confirms that the adhesive transfer method produces a phosphor film with higher surface packing density compared to other phosphor coating methods.

The device formed using the casting method, however, produced the highest color conversion efficiency at 26%. The adhesive transfer method produced a device having a color conversion efficiency of 21%. While not being bound to any theory, it is believed that the casting method yielded a phosphor film with a higher phosphor content thereby producing a device with a higher color conversion efficiency.

Color conversion efficiency was calculated using Equation 1 below. It was assumed that the wavelength range from 380 nm to 510 nm was related to color conversion efficiency, whereas the wavelength range from 510 nm to 750 nm was due to the out-coupling effect because it is known that this blue wavelength range affects color conversion.

$$Conversion efficiency = \frac{{\int }_{510}^{750} C ( λ ) λ d}{{\int }_{λ = 380}^{λ = 510} B ( λ ) λ d + {\int }_{510}^{750} C ( λ ) λ d} \\ Norm . Blue Spect . \text{:} B \\ Norm . white Spect , \text{:} W \\ Conv . Spect . \text{:} C = W - B \qquad Equation 1$$

### Example 2

### Phosphor Film Formed Using Different Sized Phosphor Particles

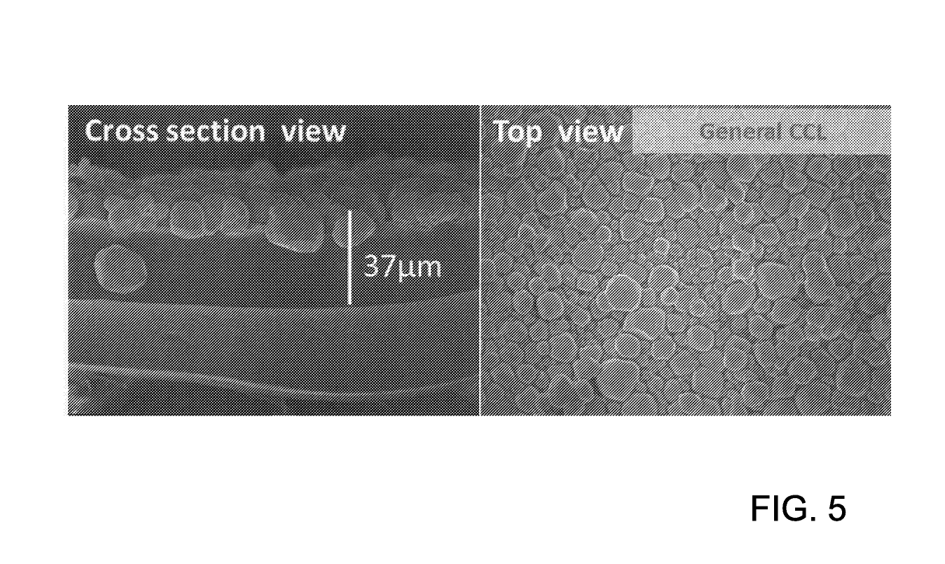

The effect of the size of the phosphor particles on the surface packing density of the resulting film was investigated. As described above, the phosphor film formed by adhesive transfer had a thickness of 37 μm and a surface packing density of 92%. The adhesive transferred phosphor film and the comparative phosphor films of Example 1 were composed of conventional phosphor particles that were sized from 10 μm to 12 μm. These conventional phosphor particles are commercially available. FIG. 5 shows enlarged cross-sectional and top views of FE-SEM photographs of the phosphor film layer composed of conventional phosphor particles formed using an adhesive transfer method. The thickness of the phosphor film is shown as 37 μm.

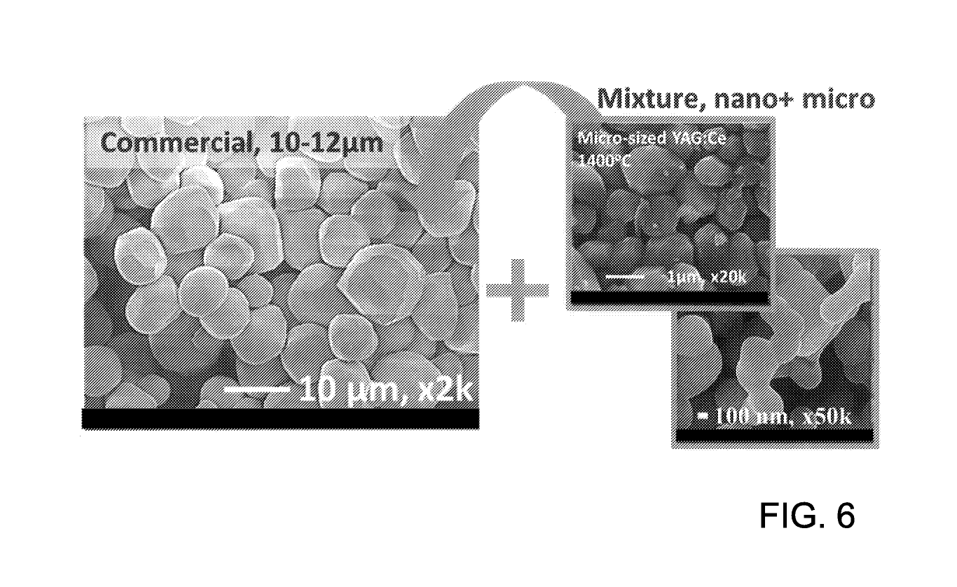

A phosphor film layer was prepared using a mixture of phosphor microparticles and phosphor nanoparticles. The phosphor microparticles were sized from 1 μm to 10 μm. The phosphor nanoparticles were sized from 10 nm to 900 nm. FIG. 6 shows enlarged top views of FE-SEM photographs of conventional sized phosphor particles and the mixture of phosphor microparticles and nanoparticles, respectively. The relative size difference between the conventional phosphor particles (Commercial, 10 μm-12 μm), and the phosphor microparticles and nanoparticles is shown in FIG. 6

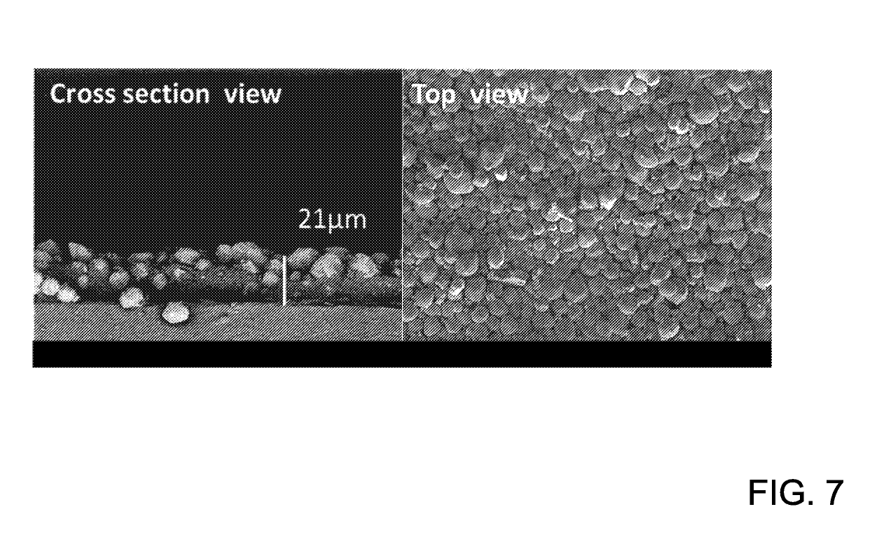

The phosphor film formed using the mixture of phosphor microparticles and nanoparticles had an improved surface packing density of 97%. Furthermore, the thickness of the phosphor film was decreased from 37 μm to 21 μm due to the increased packing density. FIG. 7 shows enlarged cross-sectional and top views of FE-SEM photographs of the phosphor film layer composed of a mixture of phosphor microparticles and nanoparticles.

The increased surface packing density of the phosphor layer reduced the number of phosphor layers needed to produce white light from a blue emitting layer from 3 to 2 phosphor film layers. Those skilled in the art will readily appreciate that a reduction in the number of phosphor film layers required for fabricating a hybrid OLED is a key advantage over the prior art.

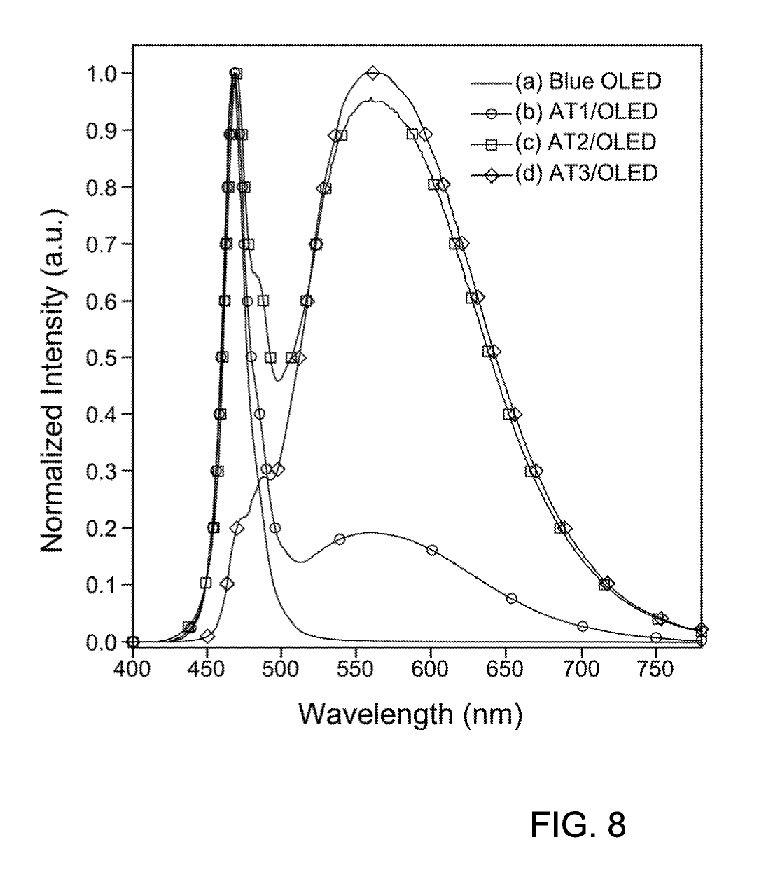

EL spectra data for a single phosphor film layer formed by adhesive transfer was compared to spectral data for two phosphor film layers and three phosphor film layers. Each phosphor layer was formed using the same mixture of phosphor microparticles and nanoparticles instead of conventional phosphor particles. Each phosphor film layer had a surface packing density of 97%. The spectral data obtained is presented in FIG. 8. As shown, there is no significant difference in EL intensity between 2 phosphor film layers and 3 phosphor film layers. The single layer of phosphor film, however, shows lower intensity compared to 2 layers of phosphor film. Therefore, using two phosphor film layers having a surface packing density of 97% is sufficient to generate the highest intensity.

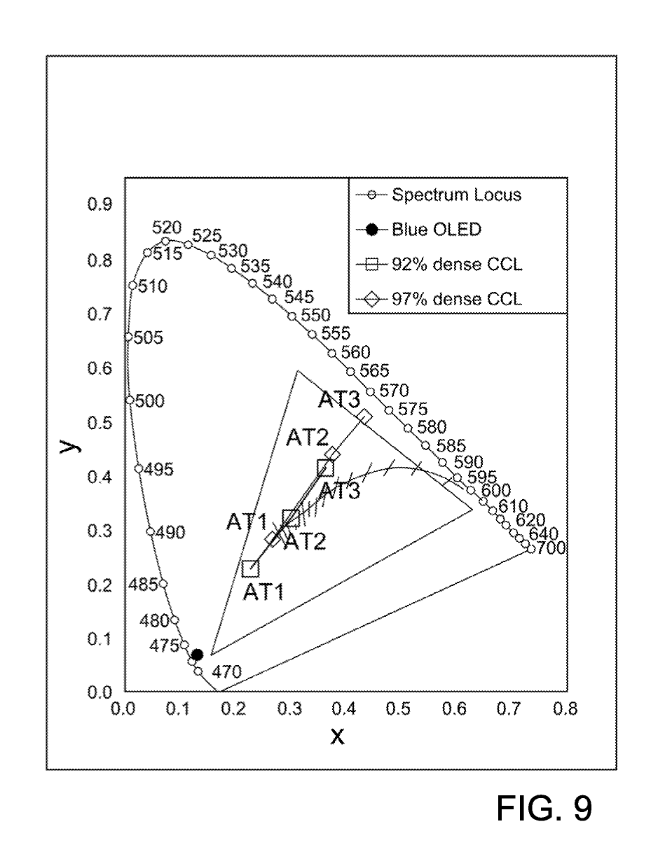

The CIE color coordinates (x,y) were also determined for the single phosphor film layer, the two layer phosphor film structure and the three layer phosphor film structure formed by adhesive transfer. The color coordinates of these structures are shown in FIG. 9. In FIG. 9, the red curve represents 97% surface packing density while the black curve represents 92% surface packing density. As shown, 2 phosphor film layers having 97% surface packing density demonstrates the same color quality as 3 phosphor film layers having 92% surface packing density. This confirms that increasing the packing density of the phosphor particles can reduce the number of phosphor layers required without sacrificing color quality.

It will be appreciated that the foregoing description provides examples of the disclosed system and technique. However, it is contemplated that other implementations of the disclosure may differ in detail from the foregoing examples. All references to the disclosure or examples thereof are intended to reference the particular example being discussed at that point and are not intended to imply any limitation as to the scope of the disclosure more generally. All language of distinction and disparagement with respect to certain features is intended to indicate a lack of preference for those features, but not to exclude such from the scope of the disclosure entirely unless otherwise indicated.

### Definitions

It is to be understood that the terminology used herein is for the purpose of describing particular aspects only and is not intended to be limiting. As used in the specification and in the claims, the term “comprising” can include the embodiments “consisting of’ and “consisting essentially of.” Unless defined otherwise, all technical and scientific terms used herein have the same meaning as commonly understood by one of ordinary skill in the art to which this disclosure belongs. In this specification and in the claims which follow, reference will be made to a number of terms which shall be defined herein.

As used in the specification and the appended claims, the singular forms “a,” “an” and “the” include plural equivalents unless the context clearly dictates otherwise. Thus, for example, reference to “a polycarbonate polymer” includes mixtures of two or more polycarbonate polymers.

As used herein, the term “combination” is inclusive of blends, mixtures, alloys, reaction products, and the like.

Ranges can be expressed herein as from one particular value to another particular value. When such a range is expressed, another aspect includes from the one particular value and/or to the other particular value. Similarly, when values are expressed as approximations, by use of the antecedent ‘about,’ it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the terms “about” and “at or about” mean that the amount or value in question can be the value designated some other value approximately or about the same. It is generally understood, as used herein, that it is the nominal value indicated ±5% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

Disclosed are the components to be used to prepare the compositions of the disclosure as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the disclosure. Thus, if there are a variety of additional steps that can be performed it is understood that each of these additional steps can be performed with any specific aspect or combination of aspects of the methods of the disclosure.

As used herein, the term “light” means electromagnetic radiation including ultraviolet, visible or infrared radiation.

As used herein, the term “transparent” means that the level of transmittance for a disclosed composition is greater than 50%. In some embodiments, the transmittance can be at least 60%, 70%, 80%, 85%, 90%, or 95%, or any range of transmittance values derived from the above exemplified values. In the definition of “transparent”, the term “transmittance” refers to the amount of incident light that passes through a sample measured in accordance with ASTM D1003 at a thickness of 3.2 millimeters.

Unless otherwise stated to the contrary herein, all test standards are the most recent standard in effect at the time of filing this application.

ASPECTS

The present disclosure comprises at least the following aspects.

Aspect 1. A composite layered structure comprising a substrate and one or more layers of phosphor film disposed on the substrate, the phosphor film comprising a resin material and a phosphor material wherein the phosphor material comprises phosphor microparticles sized from 1 μm to 10 μm and phosphor nanoparticles sized from 10 nm to 900 nm.

Aspect 2. The composite layered structure of aspect 1, wherein the phosphor film has a surface packing density that ranges from 92% to 97%.

Aspect 3. The composite layered structure of aspects 1 or 2, wherein the phosphor microparticles or the phosphor nanoparticles comprise an inorganic phosphor.

Aspect 4. The composite layered structure of any one of the preceding aspects, wherein the phosphor microparticles and phosphor nanoparticles comprise an inorganic phosphor.

Aspect 5. The composite layered structure of any one of the preceding aspects, wherein the phosphor microparticles and phosphor nanoparticles comprise yttrium aluminum oxide garnet phosphor.

Aspect 6. The composite layered structure of any one of the preceding aspects, wherein the resin material comprises silicone.

Aspect 7. The composite layered structure of any one of the preceding aspects, wherein the content of the resin material in the phosphor film is from 1 to 10 wt %.

Aspect 8. The composite layered structure of any one of the preceding aspects, wherein the phosphor film has a thickness that ranges from 21 μm to 37 μm.

Aspect 9. The composite layered structure of any one of the preceding aspects, wherein the one or more layers of phosphor film is in direct contact with the substrate.

Aspect 10. The composite layered structure of any one of the preceding aspects, wherein the one or more layers of phosphor film are disposed on the substrate using an adhesive transfer method.

Aspect 11. The composite layered structure of aspect 10, wherein the adhesive transfer method comprises the steps of: (a) providing a layer of phosphor film on a support layer; (b) transferring the layer of phosphor film to the substrate by forming a bond between the layer of phosphor film and the substrate; and (c) separating the support layer from the layer of phosphor film.

Aspect 12. The composite layered structure of aspect 11, wherein the transferring the layer of phosphor film to the substrate further comprises depositing an adhesive material on the substrate.

Aspect 13. The composite layered structure of aspect 11, wherein the transferring the layer of phosphor film to the substrate further comprises depositing an adhesive material on the surface of the phosphor film.

Aspect 14. The composite layered structure of aspect 11, wherein the transferring the layer of phosphor film to the substrate further comprises depositing an adhesive material to the surface of the substrate and the surface of the layer of phosphor film.

Aspect 15. The composite layered structure of aspects 11-14, wherein the adhesive material comprises a glue, resin, wax, metal or alloy.

Aspect 16. The composite layered structure of aspect 11, wherein the adhesive transfer method further comprises the step of heat treating the adhesive material prior to the separating the support layer from the layer of phosphor film.

Aspect 17. The composite layered structure of any one of the preceding aspects, wherein the one or more layers of phosphor film are applied sequentially.

Aspect 18. The composite layered structure of any one of the preceding aspects, wherein the one or more layers of phosphor film comprises a red-emitting phosphor.

Aspect 19. The composite layered structure of any one of the preceding aspects, wherein the one or more layers of phosphor film comprises a green-emitting phosphor.

Aspect 20. The composite layered structure of any one of the preceding aspects, wherein the one or more layers of phosphor film comprises a yellow-emitting phosphor.

Aspect 21. The composite layered structure of any one of the preceding aspects, wherein the substrate is flexible.

Aspect 22. The composite layered structure of any one of the preceding aspects, wherein the substrate comprises glass, PC, PET, PES, PEN, PMMA or combinations thereof.

Aspect 23. The composite layered structure of any one of the preceding aspects, wherein the substrate has a reflective surface and the one or more layers of phosphor film are disposed on the reflective surface of the substrate.

Aspect 24. The composite layered structure of any one of the preceding aspects, further comprising an encapsulation layer disposed over the one or more layers of phosphor film.

Aspect 25. The composite layered structure of aspect 24, wherein the encapsulation layer comprises silicone, polyurethane, epoxy, polycarbonate, poly(methylmethacrylate) or combinations thereof.

Aspect 26. The composite layered structure of any one of the preceding aspects, wherein the one or more layers of phosphor film comprises a first layer of phosphor film disposed on a surface of the substrate and a second layer of phosphor film disposed on the first layer of phosphor film opposite the substrate.

Aspect 27. The composite layered structure of aspect 26, wherein the first layer of phosphor film is disposed on the substrate using an adhesive transfer method and the second layer of phosphor film is disposed on the first layer of the phosphor film using an adhesive transfer method.

Aspect 28. The composite layered structure of aspects 26-27, wherein the composition of the first layer of phosphor film and the composition of the second layer of phosphor film are not the same.

Aspect 29. The composite layered structure of aspects 26-27, wherein the composition of the first layer of phosphor film and the composition of the second layer of phosphor film are the same.

Aspect 30. The composite layered structure of aspects 26-27, wherein the first layer of phosphor film and the second layer of phosphor film have the same thickness.

Aspect 31. The composite layered structure of aspects 26-27, wherein the first layer of phosphor film and the second layer of phosphor film each have a thickness that is 21 μm or less and a packing density that is at least 97%.

Aspect 32. The composite layered structure of any one of the preceding aspects, further comprising one or more whitening layers including whitening particles, wherein the one or more whitening layers are disposed on the one or more layers of phosphor film opposite the substrate and are configured to whiten the appearance of the composite layered structure under ambient light.

Aspect 33. The composite layered structure of aspect 32, wherein the whitening particles comprise metal oxides including TiO₂, Al₂O₃, ZrO, ZnO or mixtures thereof.

Aspect 34. The composite layered structure of aspects 32-33, wherein the one or more whitening layers comprises whitening microparticles sized from 1 μm to 10 μm and whitening nanoparticles sized from 10 nm to 900 nm.

Aspect 35. The composite layered structure of aspects 32-34, wherein the one or more whitening layers are applied to the one or more layers of phosphor film using an adhesive transfer method.

Aspect 36. The composite layered structure of aspects 32-35, further comprising an encapsulation layer surrounding the one or more whitening layers.

Aspect 37. The composite layered structure of aspect 36, wherein the encapsulation layer comprises silicone, polyurethane, epoxy, polycarbonate, poly(dimethyl siloxane), poly(methylmethacrylate) or combinations thereof.

Aspect 38. A light-emitting device comprising a light source operably connected to the composite layered structure of any of the preceding aspects.

Aspect 39. The light-emitting device of aspect 38, wherein the light source comprises a light emitting diode.

Aspect 40. The light-emitting device of aspects 38-39, wherein the light source is configured to emit light at a first color and the one or more phosphor layers are configured to convert at least a portion of the first color to a second color.

Aspect 41. The light-emitting device of aspect 40, wherein the first color is a non-white color and the second color is white.

Aspect 42. The light-emitting device of aspects 41, wherein the light source is a LED configured to emit blue light.

Aspect 43. The light-emitting device of aspects 38-42, wherein the device is configured to have a white appearance when the device is in an off-state.

Aspect 44. The light-emitting device of aspects 38-43, wherein the one or more layers of phosphor film are disposed on the substrate using an adhesive transfer method.

Aspect 45. The light-emitting device of aspect 44, wherein the adhesive transfer method comprises the steps of: (a) providing a layer of phosphor film on a support layer; (b) transferring the layer of phosphor film to the substrate by forming a bond between the layer of phosphor film and the substrate; and (c) separating the support layer from the layer of phosphor film.

Aspect 46. The light-emitting device of aspect 44, wherein the transferring the layer of phosphor film to the substrate further comprises depositing an adhesive material on the substrate.

Aspect 47. The light-emitting device of aspect 44, wherein the transferring the layer of phosphor film to the substrate further comprises depositing an adhesive material on the surface of the phosphor film.

Aspect 48. The light-emitting device of aspect 44, wherein the transferring the layer of phosphor film to the substrate further comprises depositing an adhesive material to the surface of the substrate and the surface of the layer of phosphor film.

Aspect 49. A light-emitting device comprising: a light source operably connected to a composite layered structure including a substrate and one or more layers of phosphor film disposed on the substrate, wherein the phosphor film comprises a resin material, phosphor microparticles sized from 1 μm to 10 μm and phosphor nanoparticles sized from 10 nm to 900 nm and the one or more layers of phosphor film has a surface packing density that ranges from 92% to 97%.

1. A composite layered structure comprising a substrate and one or more layers of phosphor film disposed on the substrate, wherein the one or more layers of phosphor film are disposed on the substrate using an adhesive transfer method, wherein the phosphor film comprises a resin material and a phosphor material, and wherein the phosphor material comprises phosphor microparticles sized from 1 μm to 10 μm and phosphor nanoparticles sized from 10 nm to 900 nm.

2. The composite layered structure of claim 1, wherein the phosphor film has a surface packing density that ranges from 92% to 97%.

3. The composite layered structure of claim 1, wherein the phosphor microparticles and phosphor nanoparticles comprise yttrium aluminum oxide garnet phosphor.

4. The composite layered structure of claim 1, wherein the phosphor film has a thickness that ranges from 20 μm to 40 μm.

5. The composite layered structure of claim 1, wherein the one or more layers of phosphor film is in direct contact with the substrate.

6. (canceled)

7. The composite layered structure of claim 1, wherein the adhesive transfer method comprises the steps of:
(a) providing a layer of phosphor film on a support layer;
(b) transferring the layer of phosphor film to the substrate by forming a bond between the layer of phosphor film and the substrate; and
(c) separating the support layer from the layer of phosphor film.

8. The composite layered structure of claim 7, wherein the transferring the layer of phosphor film to the substrate further comprises depositing an adhesive material on the surface of the substrate or the surface of the layer of phosphor film.

9. The composite layered structure of claim 1, wherein the one or more layers of phosphor film are applied sequentially.

10. The composite layered structure of claim 1, wherein the one or more layers of phosphor film comprises a first layer of phosphor film disposed on a surface of the substrate and a second layer of phosphor film disposed on the first layer of phosphor film opposite the substrate.

11. The composite layered structure of claim 10, wherein the first layer of phosphor film is disposed on the substrate using an adhesive transfer method and the second layer of phosphor film is disposed on the first layer of the phosphor film using an adhesive transfer method.

12. The composite layered structure of claim 11, wherein the first layer of phosphor film and the second layer of phosphor film each have a thickness that is 21 μm or less and a packing density that is at least 97%.

13. The composite layered structure of claim 1, further comprising one or more whitening layers including whitening particles, wherein the one or more whitening layers are disposed on the one or more layers of phosphor film opposite the substrate and are configured to whiten the appearance of the composite layered structure under ambient light.

14. The composite layered structure of claim 13, wherein the whitening particles comprise metal oxides including TiO₂, Al₂O₃, ZrO, ZnO, or mixtures thereof.

15. The composite layered structure of claim 13, wherein the one or more whitening layers comprises whitening microparticles sized from 1 μm to 10 μm and whitening nanoparticles sized from 10 nm to 900 nm.

16. The composite layered structure of claim 13, wherein the one or more whitening layers are applied to the one or more layers of phosphor film using an adhesive transfer method.

17. A light-emitting device comprising a light source operably connected to the composite layered structure of claim 1, wherein the light source comprises a light emitting diode and configured to emit light at a first color and the one or more phosphor layers are configured to convert at least a portion of the first color to a second color.

18. The light-emitting device of claim 17, wherein the first color is a non-white color and the second color is white.

19. The light-emitting device of claim 17, wherein the one or more layers of phosphor film are disposed on the substrate using an adhesive transfer method comprising the steps of:
(a) providing a layer of phosphor film on a support layer;
(b) transferring the layer of phosphor film to the substrate by forming a bond between the layer of phosphor film and the substrate; and
(c) separating the support layer from the layer of phosphor film.

20. A light-emitting device comprising: a light source operably connected to a composite layered structure including a substrate and one or more layers of phosphor film disposed on the substrate by an adhesive transfer method, wherein a layer of the one or more layers of phosphor film comprises a resin material, phosphor microparticles sized from 1 μm to 10 μm, and phosphor nanoparticles sized from 10 nm to 900 nm, and wherein the one or more layers of phosphor film has a surface packing density that ranges from 92% to 97%.
